(19) United States
(12) Patent Application Publication
(10) Pub. No.: US 2026/0060073 A1
(43) Pub. Date: Feb. 26, 2026

(54) MEMORY DEVICE

(71) Applicant: SAMSUNG ELECTRONICS CO., LTD., Suwon-si (KR)

(72) Inventors: Seonhaeng Lee, Suwon-si (KR); Namhyun Lee, Suwon-si (KR); Inhoe Kim, Suwon-si (KR); Gun-Hee Bae, Suwon-si (KR); Byoung-Wook Woo, Suwon-si (KR); Yunsung Lee, Suwon-si (KR)

(21) Appl. No.: 19/057,699

(22) Filed: Feb. 19, 2025

(30) Foreign Application Priority Data
Aug. 22, 2024 (KR) 10-2024-0113121

(51) Int. Cl. H01L 23/34; H01L 25/18; H10B 80/00; H10D 80/30

(52) U.S. Cl. CPC H01L 23/345; H01L 25/18; H10B 80/00; H10D 80/30; H01L 2225/06513; H01L 2225/06517; H01L 2225/0652; H01L 2225/06541; H01L 2225/06589

(57) ABSTRACT

An example memory device includes a logic die configured to output a control signal based on temperature data, and a first core die. The first core die includes a first plurality of memory cells configured to store data, a first temperature sensor configured to measure a temperature of the first plurality of memory cells and to output first temperature data based on the temperature of the first plurality of memory cells, and a first heating circuit configured to generate heat based on the control signal and the first temperature data.

### CROSS-REFERENCE TO RELATED APPLICATION

This application claims priority to and the benefit of Korean Patent Application No. 10-2024-0113121 filed in the Korean Intellectual Property Office on Aug. 22, 2024, the entire contents of which are incorporated herein by reference.

### BACKGROUND

A stack memory in which a plurality of dies are stacked on a substrate, such as a high bandwidth memory (HBM), has been commercialized. Accordingly, a technology for controlling a temperature of each of the plurality of dies has been researched.

Each of the plurality of dies may have different temperatures, for example, according to a degree of operation. However, when the temperatures of each of the dies are different, characteristics such as an energy band gap may be changed, which may cause a stress problem due to a temperature difference between the dies.

### SUMMARY

The present disclosure relates to a memory device capable of heating a die having a low temperature among a plurality of dies included in a stacked memory and increasing a temperature of the die.

In some implementations, a memory device includes a logic die configured to output a control signal based on temperature data, and a first core die including a first plurality of memory cells configured to store data, a first temperature sensor configured to measure a temperature of the first plurality of memory cells and to output first temperature data based on the temperature of the first plurality of memory cells, and a first heating circuit configured to generate heat based on the control signal and the first temperature data.

In some implementations, a memory device includes a plurality of core dies stacked in a first direction and configured to provide temperature data, the plurality of core dies including a first core die, a second core die, and a third core die, and a logic die configured to output a control signal based on the temperature data, wherein the plurality of core dies are configured to provide the temperature data through a first through silicon via, the first through silicon via extending through the plurality of core dies in the first direction, and wherein the second core die includes a heating circuit configured to heat the second core die based on first temperature data of the first core die, second temperature data of the second core die, third temperature data of the third core die, and the control signal.

In some implementations, a semiconductor device includes a host device, and a memory device including a logic die configured to output a control signal based on first temperature data and second temperature data, and a core die stacked on the logic die in a first direction, wherein the core die includes a first memory region including a plurality of first memory cells, a first temperature sensor configured to measure temperature of the plurality of first memory cells and to output the first temperature data based on the temperature of the plurality of first memory cells, and a first heating circuit configured to heat the plurality of first memory cells based on the control signal and the first temperature data, the first heating circuit being disposed adjacent to the host device, a second memory region including a plurality of second memory cells, a second temperature sensor configured to measure temperature of the plurality of second memory cells and to output the second temperature data based on the temperature of the plurality of second memory cells, and a second heating circuit configured to heat the plurality of second memory cells based on the control signal and the second temperature data, the second heating circuit being disposed opposite to the host device with respect to the first memory region, and wherein the control signal is configured to cause the first heating circuit to turn off and to cause the second heating circuit to turn on.

### BRIEF DESCRIPTION OF THE DRAWINGS

FIG. 1 is a schematic block diagram of an example of a semiconductor device.

FIG. 2 is a schematic block diagram of an example of a memory system.

FIG. 3 is a diagram of an example of a semiconductor device.

FIG. 4 is a diagram of an example of a semiconductor device.

FIG. 5 is a diagram of an example of a core die.

FIG. 6 is a circuit diagram of an example of a heating circuit.

FIG. 7 is a circuit diagram of an example of a heating circuit.

FIG. 8 is a diagram of an example of an operation of a multiplexer.

FIG. 9 is a flowchart of an example of a method of controlling a temperature of a core die.

FIG. 10 is a flowchart of an example of a method of controlling a temperature of a core die.

FIG. 11 is a flowchart of an example of a method of controlling a temperature of a core die.

FIG. 12 is a flowchart of an example of a method of controlling a temperature of a core die.

FIG. 13 is a flowchart of an example of a method of controlling a temperature of a core die.

FIG. 14 is a diagram of an example of a core die.

FIG. 15 is a diagram of an example of a core die.

FIG. 16 is a perspective view illustrating an example of a semiconductor device.

FIG. 17 is a perspective view illustrating an example of a semiconductor device.

FIG. 18 is a schematic block diagram of an example of a computing device.

### DETAILED DESCRIPTION

With reference to the attached drawings, implementations of the disclosure will be described in detail below so that ordinary skilled in the art may easily implement the disclosure. However, the disclosure may be implemented in many different forms and is not limited to the implementations described herein.

Also, to clearly explain the present disclosure in the drawings, parts that are not related to the description are omitted, and similar parts are given similar reference numerals throughout the specification. In the flowchart described with reference to the drawings, an operation order may be changed, several operations may be merged, a certain operation may be divided, and a specific operation may not be performed.

Also, expressions described in the singular may be interpreted as singular or plural unless explicit expressions such as “one” or “single” are used. Terms that include ordinal numbers such as first, second, etc. may be used to describe various components, but the components are not limited by these terms. These terms may be used for the purpose of distinguishing one component from another.

Hereinafter, the present disclosure will be described in more detail through examples. These examples are intended only to illustrate the present disclosure, and the scope of protection of the rights of the present disclosure is not limited by these examples.

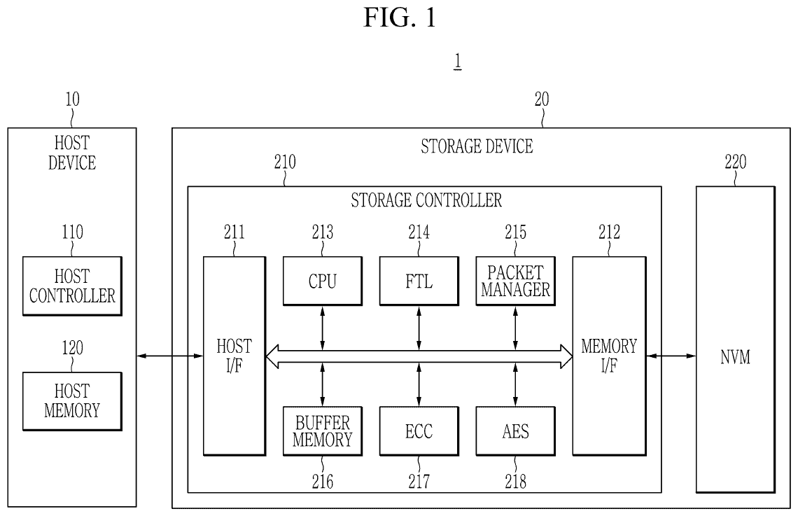

FIG. 1 is a schematic block diagram of an example of a semiconductor device.

Referring to FIG. 1, a semiconductor device 1 may be implemented as a personal computer (PC), a data server, a laptop computer, or a portable device. The portable device may be implemented as a mobile phone, a smart phone, a tablet PC, a wearable device, a personal digital assistant (PDA), an enterprise digital assistant (EDA), a digital still camera, a digital video camera, a portable multimedia player (PMP), a personal navigation device or a portable navigation device (PND), a handheld game console, or an e-book. In addition, the semiconductor device 1 may be implemented as a system-on-chip (SoC).

The semiconductor device 1 may include a host device 10 and a storage device 20. The host device 10 may communicate with the storage device 20 through various interfaces. The host device 10 may request a data processing operation, for example, a data read operation, a data program (write) operation, a data erase operation, etc., from the storage device 20. For example, the host device 10 may be a CPU, a GPU, a microprocessor, or an AP.

The host device 10 may include a host controller 110 and a host memory 120. The host memory 120 may function as a buffer memory for temporarily storing data to be transmitted to the storage device 20 or data transmitted from the storage device 20.

The storage device 20 may include a storage controller 210 and a non-volatile memory 220. The storage device 20 may include storage media for storing data in response to a request from the host device 10. For example, the storage device 20 may be implemented in various types such as an SSD, an eMMC, a UFS, a CF, an SD, a micro-SD, a mini-SD, xD, or a memory stick.

When the storage device 20 is the SSD, the storage device 20 may be a device conforming to a non-volatile memory express (NVMe) standard. When the storage device 20 is an embedded memory or an external memory, the storage device 20 may be a device conforming to a UFS standard or an eMMC standard. The host device 10 and the storage device 20 may generate and transmit packets according to the respective adopted standard protocols.

When the non-volatile memory 220 of the storage device 20 includes a flash memory, the flash memory may include a 2D NAND memory array or a 3D NAND memory array. As another example, the storage device 20 may include other various types of non-volatile memories. For example, various other types of memories such as MRAM, STT-RAM, CBRAM, FeRAM, PRAM, and RRAM may be applied to the storage device 20.

In some implementations, the host controller 110 and the host memory 120 may be implemented as separate semiconductor chips. Alternatively, in some implementations, the host controller 110 and the host memory 120 may be integrated into the same semiconductor chip. For example, the host controller 110 may be any one of a plurality of modules provided in an AP, and the AP may be implemented as a SoC. In addition, the host memory 120 may be an embedded memory provided in an AP, a non-volatile memory disposed outside the AP or a memory module.

The host controller 110 may manage an operation of storing data (e.g., program data) of a buffer region in the non-volatile memory 220 or storing data (e.g., read data) of the non-volatile memory 220 in the buffer region.

The storage controller 210 may include a host interface 211, a memory interface 212, and a CPU 213. In addition, the storage controller 210 may further include a flash transformation layer (FTL) 214, a packet manager 215, a buffer memory 216, an error correction code (ECC) engine 217, and an advanced encryption standard (AES) engine 218.

The storage controller 210 may further include a working memory in which the FTL 214 is loaded, and a data program operation and a read operation on the non-volatile memory 220 may be controlled by the CPU 213 executing the FTL 214.

The host interface 211 may transmit and receive a packet to and from the host device 10. The packet transmitted from the host device 10 to the host interface 211 may include a command or data to be programmed in the non-volatile memory 220, and the packet transmitted from the host interface 211 to the host device 10 may include a response to a command or data read from the non-volatile memory 220.

The memory interface 212 may transmit data to be programmed in the nonvolatile memory 220 to the nonvolatile memory 220 or may receive data read from the nonvolatile memory 220. The memory interface 212 may be implemented to comply with a standard protocol such as toggle or ONFI.

The FTL 214 may perform several functions such as address mapping, wear-leveling, and garbage collection. An address mapping operation is an operation of converting a logical address received from a host into a physical address used to actually store data in the non-volatile memory 220. Wear-leveling is a technology for preventing excessive deterioration of a specific block by uniformly using blocks in the non-volatile memory 220, and may be implemented through a firmware technology that balances erase counts of physical blocks. Garbage collection is a technology for securing usable capacity in the non-volatile memory 220 by copying valid data of a block to a new block and then erasing the existing block.

The packet manager 215 may generate a packet according to a protocol of an interface negotiated with the host device 10 or may parse various types of information from a packet received from the host device 10. In addition, the buffer memory 216 may temporarily store data to be programmed in the non-volatile memory 220 or data to be read from the non-volatile memory 220. The buffer memory 216 may be a component provided in the storage controller 210, but may be disposed outside the storage controller 210.

The ECC engine 217 may perform an error detection and correction function on read data to be read from the non-volatile memory 220. More specifically, the ECC engine 217 may generate parity bits with respect to write data to be written to the non-volatile memory 220, and the generated parity bits may be stored in the non-volatile memory 220 together with the program data. When reading data from the non-volatile memory 220, the ECC engine 217 may correct an error of the read data by using parity bits read from the non-volatile memory 220 together with the read data, and output the read data with the corrected error.

The AES engine 218 may perform at least one of an encryption operation and a decryption operation on data input to the storage controller 210 by using a symmetric-key algorithm.

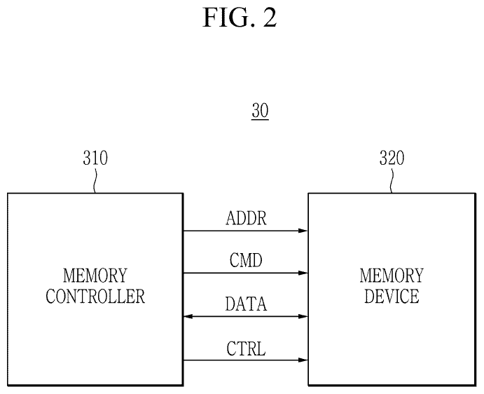

FIG. 2 is a schematic block diagram of an example of a memory system.

Referring to FIG. 2, a memory system 30 may include a memory controller 310 and a memory device 320.

The memory controller 310 may be configured to access the memory device 320 in response to a request from a host device. The memory controller 310 may be configured to provide an interface between the memory device 320 and the host device. In addition, the memory controller 310 may be configured to drive firmware for controlling the memory device 320.

The memory controller 310 may control an operation of the memory device 320. Specifically, the memory controller 310 may provide at least one of an address ADDR, a command CMD, data DATA, and a control signal CTRL along an input/output line connected to the memory device 320.

The memory controller 310 may write data to the memory device 320, erase data from the memory device 320, or read data from the memory device 320 by using at least one of the address ADDR, the command CMD, and the control signal CTRL. The control signal CTRL may include a chip enable CE, a write enable WE, a read enable RE, etc.

The memory device 320 may operate by the control of the memory controller 310. The memory device 320 may be a volatile memory such as a SRAM and a DRAM, or a non-volatile memory device such as a NAND flash memory, a vertical NAND (VNAND) flash memory, a bonding vertical NAND (BVNAND) flash memory, a NOR flash memory, a resistive random access memory (RRAM), a phase-change RAM (PRAM), a magneto resistive RAM (MRAM), a ferroelectric RAM (FRAM), a spin transfer torque RAM (STT-RAM), a conductive bridging RAM (CBRAM), etc.

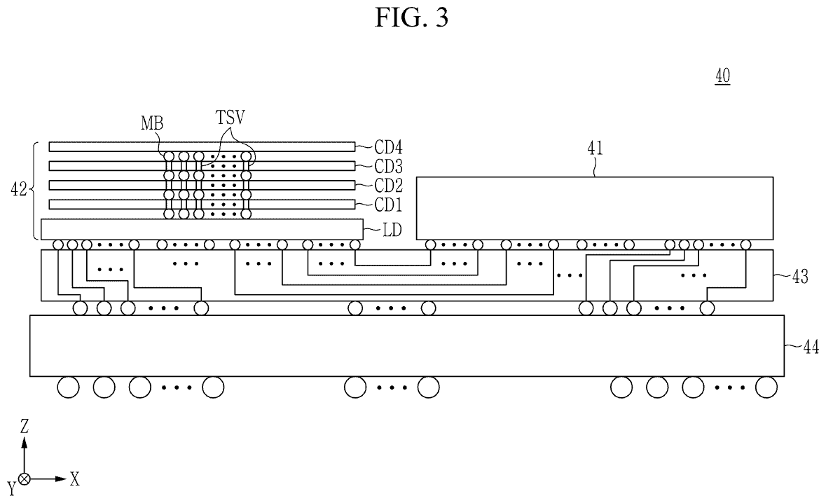

FIG. 3 is a diagram of an example of a semiconductor device.

Referring to FIG. 3, a semiconductor device 40 may include a host device 41, a memory device 42, an interposer 43, and a printed circuit board (PCB) 44. Here, the host device 41 may be substantially the same configuration as the host device 10 shown in FIG. 1. In addition, the memory device 42 may be substantially the same configuration as the storage device 20 shown in FIG. 1 or the memory device 320 shown in FIG. 2, or may be a configuration included therein.

The memory device 42 may include four core dies CD1 to CD4 and a logic die LD stacked in a first direction Z. A plurality of bumps MB may be formed between the stacked core dies CD1 to CD4 and logic die LD, and a through silicon via (TSV) penetrating the core dies CD1 to CD4 may be formed between the stacked bumps MB. As described below, temperature data with respect to each of the core dies CD1 to CD4 and a control signal for controlling each of the core dies CD1 to CD4 may be transmitted through the TSV. The plurality of bumps MB may be disposed on a lower surface of the logic die LD with respect to the first direction Z.

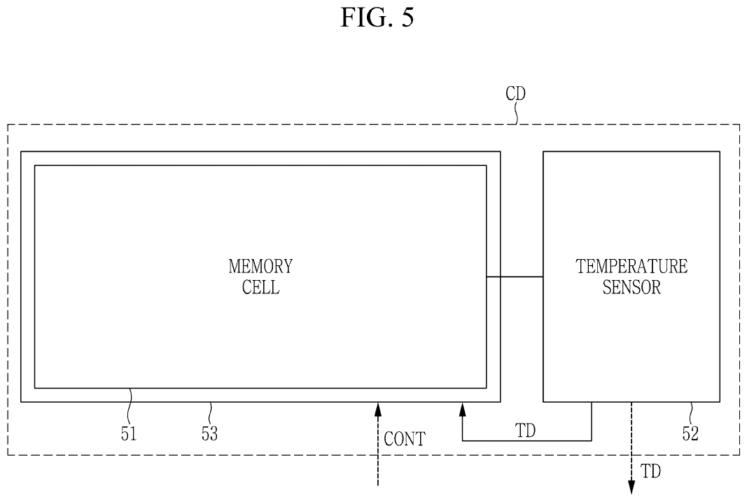

Each of the core dies CD1 to CD4 may be an HBM DRAM die, but an implementation is not limited thereto. Each of the core dies CD1 to CD4 may include a plurality of memory cells storing data, a temperature sensor measuring temperature of the plurality of memory cells and outputting temperature data, and a heating circuit generating heat based on the control signal output from the logic die LD and the temperature data. Details will be described below with reference to FIG. 5.

Meanwhile, FIG. 3 shows that the memory device 42 includes the four stacked core dies CD1 to CD4, and the logic die LD is disposed below the stacked core dies CD1 to CD4, but the implementation is not necessarily limited thereto. For example, the memory device 42 may include five or more stacked core dies, and the logic die LD may be stacked above the stacked core dies CD1 to CD4 rather than there below.

Each of the core dies CD1 to CD4 shown in FIG. 3 may be manufactured as a memory device that stores data input through data terminals in selected memory cells from among a plurality of memory cells of a memory cell array in response to a command and an address applied through command and address terminals, or outputs the data stored in the selected memory cells through data terminals.

The plurality of bumps MB may be disposed on a lower surface of the host device 41, and the plurality of bumps MB may be micro-bumps. The plurality of bumps MB may be disposed on a lower surface of the interposer 43, and the interposer 43 may include a command and an address line and a control signal line connecting the plurality of bumps MB. A plurality of balls may be disposed on a lower surface of the PCB 44, and the plurality of bumps MB and the plurality of balls may be connected to each other in the PCB 44.

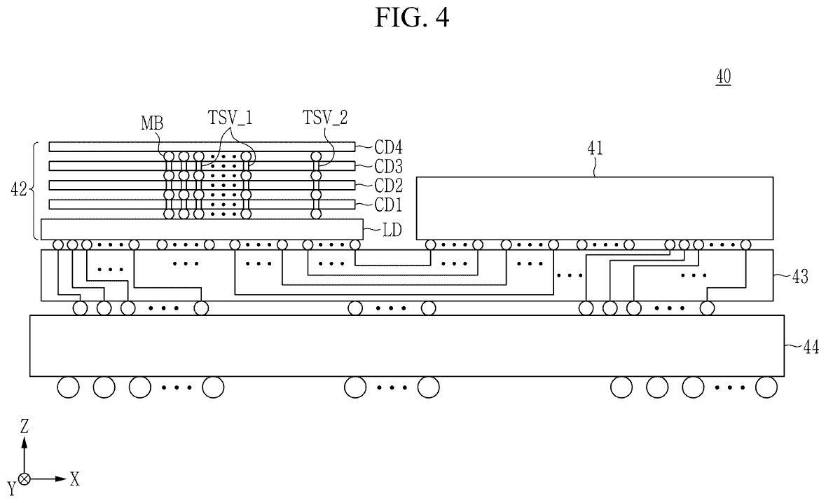

FIG. 4 is a diagram of an example of a semiconductor device.

Referring to FIG. 4, unlike the implementation shown in FIG. 3, the memory device 42 may further include a first through silicon via TSV_1 penetrating the stacked core dies CD1 to CD4, and a second through silicon via TSV_2 distinguished from the first through silicon via TSV_1 and penetrating the stacked core dies CD1 to CD4.

Each of the core dies CD1 to CD4 may provide each temperature data measured by a temperature sensor included therein to the other core dies CD1 to CD4 and the logic die LD through the first through silicon via TSV_1.

For example, the first core die CD1 may provide the temperature data measured by the temperature sensor inside to the second to fourth core dies CD2 to CD4 and the logic die LD through the first through silicon via TSV_1.

In addition, the second core die CD2 may provide the temperature data measured by the temperature sensor inside to the first core die CD1, the third core die CD3, the fourth core die CD4, and the logic die LD through the first through silicon via TSV_1.

In addition, the third core die CD3 may provide the temperature data measured by the temperature sensor inside to the first core die CD1, the second core die CD2, the fourth core die CD4, and the logic die LD through the first through silicon via TSV_1.

In addition, the fourth core die CD4 may provide the temperature data measured by the temperature sensor inside to the first to third core dies CD1 to CD3 and the logic die LD through the first through silicon via TSV_1.

The logic die LD may provide control signals to the core dies CD1 to CD4 through the second through silicon via TSV_2.

For example, the logic die LD may output the control signal for turning on a heating circuit included in the first core die CD1 to the first core die CD1 through the second through silicon via TSV_2.

In addition, the logic die LD may output the control signal for turning on a heating circuit included in the second core die CD2 to the second core die CD2 through the second through

### Silicon via Tsv_2.

In addition, the logic die LD may output the control signal for turning on a heating circuit included in the third core die CD3 to the third core die CD3 through the second through silicon via TSV_2.

In addition, the logic die LD may output a control signal for turning on a heating circuit included in the fourth core die CD4 to the fourth core die CD4 through the second through silicon via TSV_2.

Alternatively, the logic die LD may output one control signal for turning on all the heating circuits respectively included in the first to fourth core dies CD1 to CD4 to the first to fourth core dies CD1 to CD4. In this case, the first to fourth core dies CD1 to CD4 may transmit and receive the temperature data to each other, and based on the temperature data, the heating circuit included in each of the first to fourth core dies CD1 to CD4 may adjust a degree of heat radiated.

That is, the temperature data measured with respect to each of the core dies CD1 to CD4 and the control signal output from the logic die LD may be transmitted through different through silicon vias.

FIG. 5 is a diagram of an example of a core die.

Referring to FIG. 5, a core die CD (e.g., any one of the core dies CD1 to CD4) shown in FIGS. 3 and 4) may include a plurality of memory cells 51, a temperature sensor 52, and a heating circuit 53.

The plurality of memory cells 51 may store data. For example, the plurality of memory cells 51 may store input data or output stored data, in response to a command and an address input to the core die CD.

The temperature sensor 52 may measure temperature of the plurality of memory cells 51 in real time. The temperature sensor 52 may measure the temperature of the plurality of memory cells 51 and output temperature data TD. The temperature sensor 52 may provide the output temperature data TD to the heating circuit 53 and a logic die (e.g., the logic die LD shown in FIGS. 3 and 4). Herein, the temperatures of the plurality of memory cells 51 included in the specific core die CD may have the same meaning as a temperature of the specific core die CD.

The temperature data TD may indicate which temperature range among a plurality of temperature ranges belongs to the temperature of the plurality of memory cells 51 measured by the temperature sensor 52. For example, when the temperature of the plurality of memory cells 51 is in a first range (e.g., 25° C. or less), the temperature sensor 52 may output the temperature data TD having a first value, and when the temperature of the plurality of memory cells 51 is in a second range (e.g., greater than 25° C. and 100° C. or less), the temperature sensor 52 may output the temperature data TD having a second value, and when the temperature of the plurality of memory cells 51 is in a third range (e.g., greater than 100° C.), the temperature sensor 52 may output the temperature data TD having a third value.

The above-described first to third values of the temperature data TD may have different values. For example, as the temperature of the plurality of memory cells 51 is lower, the temperature data TD may have a smaller value, and accordingly, the second value may be greater than the first value but less than the third value.

A value of the temperature data TD may be expressed in a voltage. Herein, for convenience of description, it is described that the temperature data TD has a relatively higher voltage as the measured temperature of the plurality of memory cells 51 is higher, and the temperature data TD has a relatively lower voltage as the measured temperature of the plurality of

### Memory Cells 51 Is Lower.

However, the implementation is not necessarily limited thereto, and the measured temperature of the plurality of memory cells 51 may be implemented to be included in any one of three or more temperature ranges, and the relationship between the measured temperature of the plurality of memory cells 51 and the value of the temperature data TD corresponding thereto may also be variously implemented according to implementations.

The heating circuit 53 may be disposed to surround the plurality of memory cells 51. The heating circuit 53 may generate heat based on the temperature data TD provided from the temperature sensor 52 and the control signal CONT provided from the logic die (e.g., the logic die LD shown in FIGS. 3 and 4). Specifically, the heating circuit 53 may be turned on or off based on the control signal CONT, and a degree of heat radiated may vary according to the value of the temperature data TD.

The heating circuit 53 may heat the plurality of memory cells 51, more specifically, the core die CD including the heating circuit 53, by using heat generated by a Joule heating mechanism. The heating circuit 53 may consist of, for example, a poly gate or metal such as tungsten, aluminum, copper, etc., but the implementation is not necessarily limited thereto, and may include any other suitable material for a heating operation.

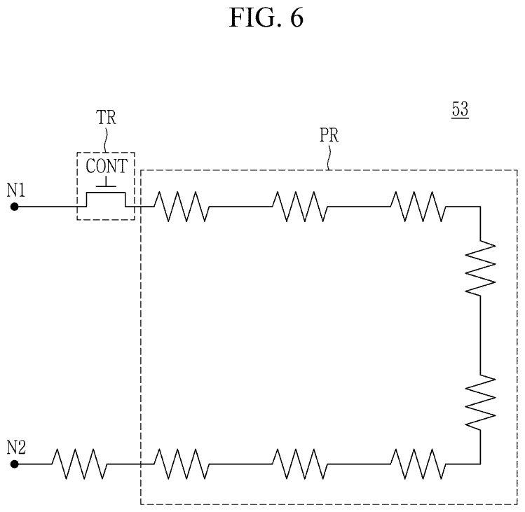

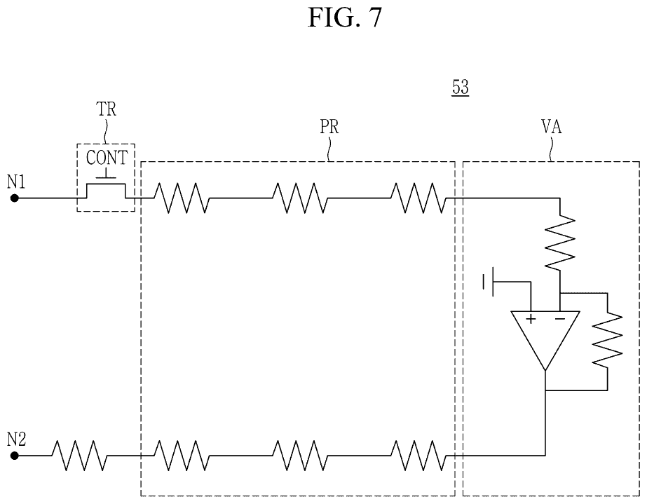

FIGS. 6 and 7 are circuit diagrams of an example of a heating circuit.

Referring to FIG. 6, the heating circuit 53 may include a transistor TR and a plurality of resistors PR.

The transistor TR may be connected between a first node N1 to which the temperature data (e.g., TD shown in FIG. 5) is applied and the plurality of resistors PR. The plurality of resistors PR may be connected between the transistor TR and a second node N2. The second node N2 may be grounded. The transistor TR and the plurality of resistors PR may be connected in series. When the transistor TR is turned on, the plurality of resistors PR may be connected between the first node N1 and the second node N2.

The control signal CONT provided from the logic die (e.g., the logic die LD shown in FIGS. 3 and 4) may be applied to a gate of the transistor TR.

When the control signal CONT is a high level (e.g., a logic value of 1), the transistor TR may be turned on, and accordingly, a current may flow through the plurality of resistors PR by a value of the temperature data applied to the first node N1. The magnitude of the current flowing through the plurality of resistors PR may vary according to a voltage level of the temperature data applied to the first node N1. The current flowing through the plurality of resistors PR may generate heat by a Joule heating mechanism.

On the other hand, when the control signal CONT is a low level (e.g., a logic value of 0), the transistor TR may be turned off, and accordingly, the heating circuit 53 may not operate.

Meanwhile, when the temperature data received from a core die is greater than or equal to a specific value, the logic die may output the control signal CONT having a bias voltage to break down the transistor TR. For example, when a temperature of a core die is excessively high, the logic die may apply the control signal CONT having the bias voltage to a transistor of a heating circuit included in the core die to control the heating circuit not to operate.

Referring to FIG. 7, the heating circuit 53 may further include at least one voltage amplifier VA connected between the plurality of resistors PR and the second node N2. When a length of a line between the first node N1 and the second node N2 is greater than or equal to a certain length, heating due to the plurality of resistors PR may not sufficiently occur due to a current leakage, etc., and to compensate for this, the voltage amplifier VA may amplify a voltage at a specific point of the heating circuit 53 so that sufficient heating by the plurality of resistors PR is guaranteed. The heating circuit 53 may include a corresponding number of voltage amplifiers VA according to the length of the line.

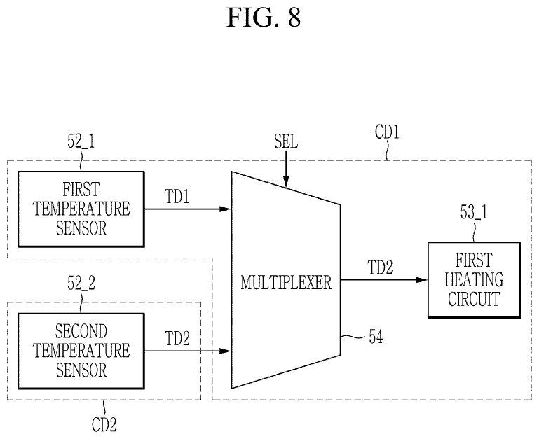

FIG. 8 is a diagram of an example of an operation of a multiplexer.

Referring to FIG. 8, a core die may further include a multiplexer 54. The multiplexer 54 may output any one of first temperature data TD1 provided from a first temperature sensor 52_1 and second temperature data TD2 provided from a second temperature sensor 52_2, based on a selection signal SEL provided from the logic die (e.g., the logic die LD shown in FIGS. 3 and 4).

The multiplexer 54 may be included in the first core die CD1, or may be included in the second core die CD2. Alternatively, the multiplexer 54 may be included in both the first core die CD1 and the second core die CD2. In FIG. 8, it is described that the multiplexer 54 is included in the first core die CD1.

The first temperature sensor 52_1 may be included in the first core die CD1, and the first temperature sensor 52_1 may output the temperature data TD1 with respect to the first core die CD1. The second temperature sensor 52_2 may be included in the second core die CD2, and the second temperature sensor 52_2 may output the temperature data TD2 with respect to the second core die CD2.

For example, when a temperature of the first core die CD1 is lower than a temperature of the second core die CD2, a value of the first temperature data TD1 may be less than a value of the second temperature data TD2.

The multiplexer 54 may output the second temperature data TD2 having a greater value among the first temperature data TD1 and the second temperature data TD2 to a first heating circuit 53_1 included in the first core die CD1, based on the selection signal SEL provided from the logic die.

Here, the selection signal SEL may be a signal for determining the multiplexer 54 to output a specific one of several inputs, based on a result of the logic die receiving the first temperature data TD1 and the second temperature data TD2 and comparing the respective values of the first temperature data TD1 and the second temperature data TD2. The selection signal SEL may be a signal included in the control signal (e.g., the control signal CONT shown in FIG. 5) output from the logic die, but the implementation is not necessarily limited thereto.

Instead of the previously received first temperature data TD1, the first heating circuit 53_1 may receive the second temperature data TD2 having a larger value than the first temperature data TD1. Accordingly, the first heating circuit 53_1 may generate more heat than the first temperature data TD1 being input, and the temperature of the first core die CD1 may increase and be substantially the same as the temperature of the second core die CD2.

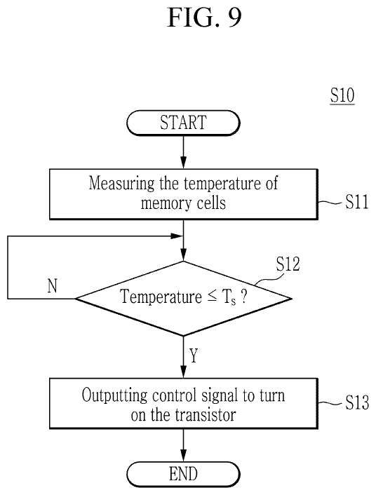

FIG. 9 is a flowchart of an example of a method of controlling a temperature of a core die.

Referring to FIG. 9, the method S10 of controlling the temperature of the core die may include step S11 of measuring temperature of a plurality of memory cells. For example, referring to FIG. 5, the temperature sensor 52 included in the core die CD may measure temperature of the plurality of memory cells 51 and output the temperature data TD.

The method S10 of controlling the temperature of the core die may include step S12 of determining whether the measured temperature is less than or equal to a predetermined specific temperature. For example, referring to FIGS. 3 to 5, the logic die LD may receive the temperature data TD with respect to the corresponding core die CD from the temperature sensor 52 included in the core die CD, and may determine whether a value of the temperature data TD is less than or equal to the predetermined specific value.

The method S10 of controlling the temperature of the core die may include step S13 of outputting a control signal to turn on a transistor when the measured temperature is below the predetermined specific temperature (Y). For example, referring to FIGS. 3 to 7, the logic die LD may output the control signal CONT to turn on the transistor TR of the heating circuit 53 included in the core die CD to control the heating circuit 53 to operate, in order to increase a temperature of the core die CD.

When the measured temperature is higher than the predetermined specific temperature (N), step S12 of determining whether the measured temperature is less than or equal to the predetermined specific temperature may be performed again.

Meanwhile, referring to FIGS. 3 and 4, a specific temperature previously determined with respect to each of the first to fourth core dies CD1 to CD4 and a value of temperature data corresponding thereto may be different from each other. For example, while heating circuits respectively included in the first to fourth core dies CD1 to CD4 are not all turned on, the first core die CD1 stacked on the logic die LD may generally have a higher temperature than the fourth core die CD4 due to heat generated by an operation of the logic die LD. Therefore, the temperature at which the heating circuit included in the fourth core die CD4 starts to turn on may be lower than the temperature at which the heating circuit included in the first core die CD1 starts to turn on.

That is, the predetermined specific temperature with respect to the first core die CD1 may be higher than the predetermined specific temperature with respect to the second core die CD2, the predetermined specific temperature with respect to the second core die CD2 may be higher than the predetermined specific temperature with respect to the third core die CD3, and the predetermined specific temperature with respect to the third core die CD3 may be higher than the predetermined specific temperature with respect to the fourth core die CD4.

In addition, to correspond to this, the value of the temperature data corresponding to the predetermined specific temperature of the first core die CD1 may be greater than the value of the temperature data corresponding to the predetermined specific temperature of the second core die CD2, the value of the temperature data corresponding to the predetermined specific temperature of the second core die CD2 may be greater than the value of temperature data corresponding to the predetermined specific temperature of the third core die CD3, and the value of the temperature data corresponding to the predetermined specific temperature of the third core die CD3 may be greater than the value of the temperature data corresponding to the predetermined specific temperature of the fourth core die CD4.

Accordingly, when the value of the temperature data of the first core die CD1 is less than or equal to the value of the temperature data corresponding to the predetermined specific temperature with respect to the first core die CD1, the logic die LD may output the control signal CONT to turn on the heating circuit included in the first core die CD1 in order to heat the first core die CD1.

Similarly, when the value of the temperature data of the second core die CD2 is less than or equal to the value of temperature data corresponding to the predetermined specific temperature with respect to the second core die CD2, the logic die LD may output the control signal CONT to turn on the heating circuit included in the second core die CD2 in order to heat the second core die CD2.

Similarly, when the value of the temperature data of the third core die CD3 is less than or equal to the value of temperature data corresponding to the predetermined specific temperature with respect to the third core die CD3, the logic die LD may output the control signal CONT to turn on the heating circuit included in the third core die CD3 in order to heat the third core die CD3.

Similarly, when the value of the temperature data of the fourth core die CD4 is less than or equal to the value of temperature data corresponding to the predetermined specific temperature with respect to the fourth core die CD4, the logic die LD may output the control signal CONT to turn on the heating circuit included in the fourth core die CD4 in order to heat the fourth core die CD4.

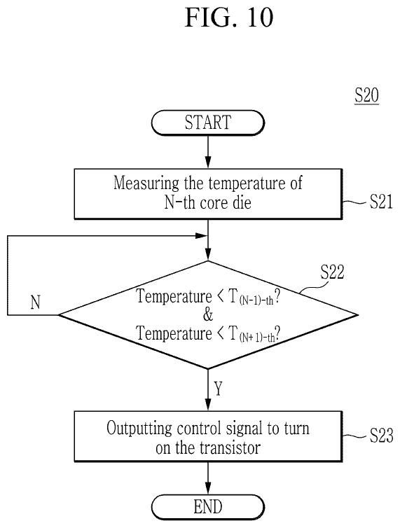

FIG. 10 is a flowchart of an example of a method of controlling a temperature of a core die.

Referring to FIG. 10, a method S20 of controlling the temperature of the core die may include step S21 of measuring a temperature of an Nth core die. For example, referring to FIGS. 3 to 5, the temperature sensor 52 included in the second core die CD2 may measure the temperature of the second core die CD2 by measuring the temperature of the plurality of memory cells 51 included in the second core die CD2, and may output the temperature data TD.

The method S20 of controlling the temperature of the core die may include step S22 of determining whether the temperature of the Nth core die is lower than a temperature of an N−1th core die and lower than a temperature of an N+1th core die.

For example, referring to FIGS. 3 to 5, the logic die LD may receive the temperature data TD with respect to each of the first to third core dies CD1 to CD3 from a temperature sensor included in each of the first to third core dies CD1 to CD3.

The logic die LD may determine whether a value of the temperature data of the second core die CD2 is less than a value of the temperature data of the first core die CD1 and a value of the temperature data of the third core die CD3, and determine whether the temperature of the second core die CD2 is lower than a temperature of the first core die CD1 and lower than a temperature of the third core die CD3.

The method S20 of controlling the temperature of the core die may include step S23 of outputting a control signal to turn on a transistor when the temperature of the Nth core die is lower than the temperature of the N-1th core die and lower than the temperature of the N+1th core die (Y).

For example, referring to FIGS. 3 to 7, the logic die LD may output the control signal CONT to turn on the transistor TR of the heating circuit 53 included in the second core die CD2 to the second core die CD2 to control the heating circuit 53 included in the second core die CD2 to operate, in order to increase the temperature of the second core die CD2 lower than the temperature of the first core die CD1 and the temperature of the third core die CD3.

When the temperature of the Nth core die is higher than the temperature of the N−1th core die or higher than the temperature of the N+1th core die (N), step S22 of determining whether the temperature of the Nth core die is lower than the temperature of the N−1th core die and lower than the temperature of the N+1th core die may be performed again.

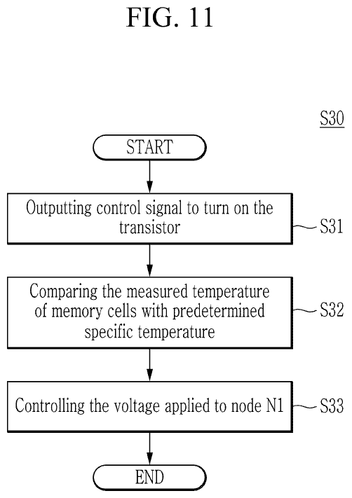

FIG. 11 is a flowchart of an example of a method of controlling a temperature of a core die.

Referring to FIG. 11, a method S30 of controlling the temperature of the core die may include step S31 of outputting a control signal to turn on a transistor. For example, referring to FIGS. 3 to 7, the logic die LD may output the control signal CONT to turn on the transistor TR of the heating circuit 53 included in the core die CD to control the heating circuit 53 to operate, in order to increase a temperature of the core die CD.

The method S30 of controlling the temperature of the core die may include step S32 of comparing the measured temperature of memory cells with a predetermined specific temperature. For example, referring to FIGS. 3 to 5, the logic die LD may receive the temperature data TD with respect to the core die CD from the temperature sensor 52 included in the core die CD, and may compare a value of the temperature data TD with a value of the temperature data corresponding to the predetermined specific temperature.

The method S30 of controlling the temperature of the core die may include step S33 of adjusting a voltage applied to a first node. For example, referring to FIGS. 3 to 8, when the temperature of the corresponding core die CD is lower than that of other core dies, the logic die LD may output the selection signal SEL, which causes a higher voltage to be applied to the first node N1 of the heating circuit 53 and the heating circuit 53 to generate heat relatively strongly, to the multiplexer 54.

On the contrary, when the temperature of the corresponding core die CD is higher than those of other core dies, the logic die LD may output the selection signal SEL, which causes a lower voltage to be applied to the first node N1 of the heating circuit 53 and the heating circuit 53 to generate heat relatively weakly, to the multiplexer 54.

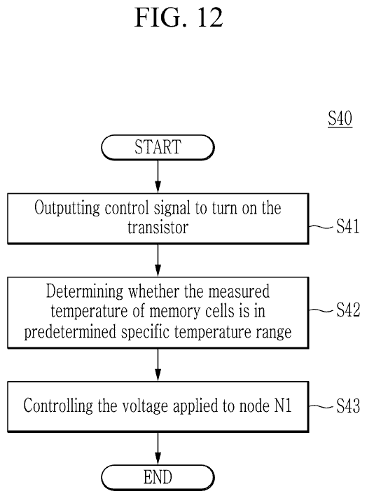

FIG. 12 is a flowchart of an example of a method of controlling a temperature of a core die.

Referring to FIG. 12, a method S40 of controlling the temperature of the core die may include step S41 of outputting a control signal to turn on a transistor. For example, referring to FIGS. 3 to 7, the logic die LD may output the control signal CONT to turn on the transistor TR of the heating circuit 53 included in the corresponding core die CD to control the heating circuit 53 to operate, in order to increase the temperature of the core die CD.

The method S40 of controlling the temperature of the core die may include step S42 of determining whether the measured temperature of memory cells is within a predetermined specific temperature range. For example, referring to FIGS. 3 to 5, the logic die LD may receive the temperature data TD with respect to the corresponding core die CD from the temperature sensor 52 included in the core die CD, and may determine whether a value of the temperature data TD is included in a range of a value of the temperature data corresponding to the predetermined specific temperature range.

The method S40 of controlling the temperature of the core die may include step S43 of adjusting a voltage applied to a first node. For example, referring to FIGS. 3 to 8, when the temperature of the corresponding core die CD is lower than a predetermined temperature range, the logic die LD may output the selection signal SEL, which causes a higher voltage to be applied to the first node N1 of the heating circuit 53 and the heating circuit 53 to generate heat relatively strongly, to the multiplexer 54.

On the contrary, when the temperature of the core die CD is higher than the predetermined temperature range, the logic die LD may output the selection signal SEL, which causes a lower voltage to be applied to the first node N1 of the heating circuit 53 and the heating circuit 53 to generate heat relatively weakly, to the multiplexer 54.

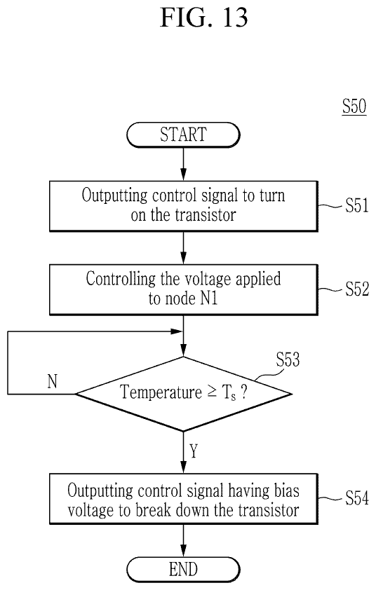

FIG. 13 is a flowchart of an example of a method of controlling a temperature of a core die.

Referring to FIG. 13, a method S50 of controlling the temperature of the core die may include step S51 of outputting a control signal to turn on a transistor. For example, referring to FIGS. 3 to 7, the logic die LD may output the control signal CONT to turn on the transistor TR of the heating circuit 53 included in the corresponding core die CD to control the heating circuit 53 to operate, in order to increase the temperature of the core die CD.

The method S50 of controlling the temperature of the core die may include step S52 of adjusting a voltage applied to a first node. For example, referring to FIGS. 3 to 7, the higher the measured temperature of the core die CD, the voltage of the temperature data TD output from the temperature sensor 52 may be set to have a relatively smaller value, and the lower the measured temperature of the core die CD, the voltage of the temperature data TD output from the temperature sensor 52 may be set to have a relatively greater value.

For example, when the temperature of the first core die CD1 is high, because the voltage of the temperature data TD input to the first node N1 has a relatively small value, a heating amount of the heating circuit 53 may be relatively small. Specifically, the temperature sensor 52 may output a first voltage when the temperature of the first core die CD1 is within a first range, which is a low temperature range, output a second voltage, which is lower than the first voltage, when the temperature is within a second range, which is an intermediate temperature range, and output a third voltage, which is lower than the second voltage, when the temperature is within a third range, which is a high temperature range.

When the third voltage is applied to the first node N1 of the heating circuit (53 of FIG. 5), and the same voltage as the third voltage is also applied to the second node N2, no current may flow through the plurality of resistors PR. Therefore, when the temperature of the first core die CD1 is within the high temperature range, the heating circuit 53 may not generate heat.

When the second voltage is applied to the first node N1 of the heating circuit 53 and the same voltage as the third voltage is also applied to the second node N2, a relatively low current may flow through the plurality of resistors PR due to a relatively small voltage difference between the second voltage and the third voltage. Therefore, when the temperature of the first core die CD1 is within the intermediate temperature range, the heating amount of the heating circuit 53 may be relatively small.

When the first voltage is applied to the first node N1 of the heating circuit 53 and the same voltage as the third voltage is also applied to the second node N2, a relatively high current may flow through the plurality of resistors PRs due to a relatively large voltage difference between the first voltage and the third voltage. Therefore, when the temperature of the first core die CD1 is within the low temperature range, the heating amount of the heating circuit 53 may be relatively large.

That is, while comparing the temperatures of the plurality of core dies CD1 to CD4 by the logic die LD and not performing control accordingly, the temperatures of the first core die CD1 and the second core die CD2 may be substantially the same.

The method S50 of controlling the temperature of the core die may include step S53 of determining whether the temperature of the core die is greater than or equal to a predetermined specific temperature. For example, referring to FIGS. 3 to 5, the logic die LD may determine whether the temperature of the core die CD is greater than or equal to the predetermined specific temperature based on the temperature data TD with respect to the corresponding core die CD from the temperature sensor 52 included in the core die CD.

The method S50 of controlling the temperature of the core die may include step S54 of outputting a control signal having a bias voltage to break down the transistor when the temperature of the core die is greater than or equal to the predetermined specific temperature (Y). For example, referring to FIGS. 3 to 7, when the temperature of the core die CD is greater than or equal to the specific temperature, the logic die LD may output the control signal CONT having the bias voltage to break down the transistor TR of the heating circuit 53 included in the core die CD to control the heating circuit 53 not to operate.

When the measured temperature is lower than the predetermined specific temperature (N), step S53 of determining whether the temperature of the core die is greater than or equal to the predetermined specific temperature may be performed again.

The method of controlling the temperature of the core die shown in FIG. 9 to FIG. 13 are shown as being performed individually, but the implementations are not limited thereto. The method of controlling the temperature of the core die shown in FIG. 9 to FIG. 12 may be organically combined and performed so that temperatures of a plurality of core dies are maintained substantially the same as each other.

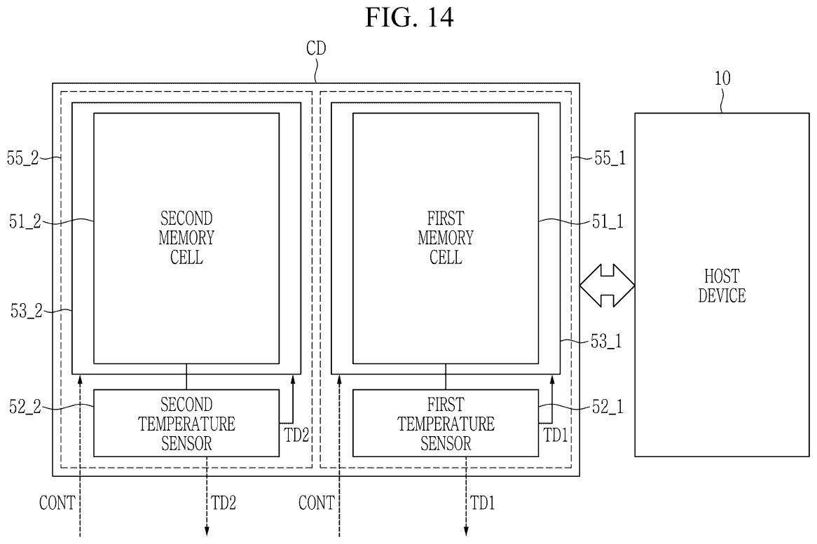

FIG. 14 is a diagram of an example of a core die.

Referring to FIG. 14, the core die CD may be mounted on the same substrate together with the host device 10 and implemented as a semiconductor device. The core die CD may include a first memory region 55_1 and a second memory region 55_2 which are distinguished according to an arrangement relationship with the host device 10.

Specifically, the first memory region 55_1 may be a memory region of the core die CD that is disposed adjacent to the host device 10, and the second memory region 55_2 may be a memory region that is opposite to the host device 10 with respect to the first memory region 55_1. In this regard, the area of the first memory region 55_1 may be the same as the area of the second memory region 55_2, but the implementation is not necessarily limited thereto.

The first memory region 55_1 may include a plurality of first memory cells 51_1, the first temperature sensor 52_1 that measures temperature of the plurality of first memory cells 51_1 to output the first temperature data TD1, and the first heating circuit 53_1 that heats the plurality of first memory cells 51_1 based on the control signal CONT and the first temperature data TD1.

The second memory region 55_2 may include a plurality of second memory cells 51_2, the second temperature sensor 52_2 that measures temperature of the plurality of second memory cells 51_2 to output the second temperature data TD2, and a second heating circuit 53_2 that heats the plurality of second memory cells 51_2 based on the control signal CONT and the second temperature data TD2.

When both the first heating circuit 53_1 and the second heating circuit 53_2 are not turned on, a temperature of the first memory region 55_1 may be generally higher than a temperature of the second memory region 55_2 due to heat generated by an operation of the host device 10. Accordingly, temperature control with respect to the core die CD may be performed so that the temperature of the second memory region 55_2 is maintained the same as the temperature of the first memory region 55_1.

Specifically, the logic die (e.g., the logic die LD shown in FIGS. 3 and 4) may receive the first temperature data TD1 with respect to the first memory region 55_1 from the first temperature sensor 52_1 and the second temperature data TD2 with respect to the second memory region 55_2 from the second temperature sensor 52_2.

Because the temperature of the first memory region 55_1 is higher than the temperature of the second memory region 55_2, a value of the first temperature data TD1 may be greater than a value of the second temperature data TD2. The logic die LD may determine that the temperature of the second memory region 55_2 is lower than the temperature of the first memory region 55_1 based on the value of the first temperature data TD1 and the value of the second temperature data TD2.

The logic die LD may provide the control signal CONT to turn off the first heating circuit 53_1 to the first heating circuit 53_1, and may provide the control signal CONT to turn on the second heating circuit 53_2 to the second heating circuit 53_2 so that the temperatures of the first memory region 55_1 and the second memory region 55_2 are maintained the same.

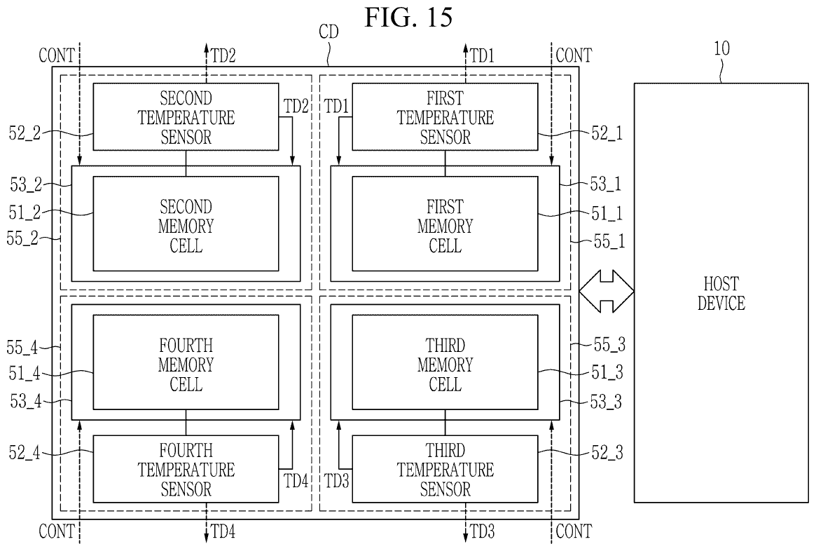

FIG. 15 is a diagram of an example of a core die.

Referring to FIG. 15, the core die CD may be mounted on the same substrate together with the host device 10 and implemented as a semiconductor device. The core die CD may include the first memory region 55_1, the second memory region 55_2, a third memory region 55_3, and a fourth memory region 55_4, which are distinguished according to an arrangement relationship with the host device 10.

Specifically, the first memory region 55_1 and the third memory region 55_3 may be memory areas of the core die CD that are disposed adjacent to the host device 10, and the second memory region 55_2 and the fourth memory region 55_4 may be memory areas that are opposite to the host device 10 with respect to the first memory region 55_1 and the third memory region 55_3. In this regard, areas of the first memory region 55_1, the second memory region 55_2, the third memory region 55_3, and the fourth memory region 55_4 may be the same, but the implementation is not necessarily limited thereto.

The first memory region 55_1 may include the plurality of first memory cells 51_1, the first temperature sensor 52_1 that measures temperature of the plurality of first memory cells 51_1 to output the first temperature data TD1, and the first heating circuit 53_1 that heats the plurality of first memory cells 51_1 based on the control signal CONT and the first temperature data TD1.

The second memory region 55_2 may include the plurality of second memory cells 51_2, the second temperature sensor 52_2 that measures temperature of the plurality of second memory cells 51_2 to output the second temperature data TD2, and the second heating circuit 53_2 that heats the plurality of second memory cells 51_2 based on the control signal CONT and the second temperature data TD2.

The third memory region 55_3 may include a plurality of third memory cells 51_3, a third temperature sensor 52_3 that measures temperature of the plurality of third memory cells 51_3 to output third temperature data TD3, and a third heating circuit 53_3 that heats the plurality of third memory cells 51_3 based on the control signal CONT and the third temperature data TD3.

The fourth memory region 55_4 may include a plurality of fourth memory cells 51_4, a fourth temperature sensor 52_4 that measures temperature of the plurality of fourth memory cells 51_4 to output fourth temperature data TD4, and a fourth heating circuit 53_4 that heats the plurality of fourth memory cells 51_4 based on the control signal CONT and the fourth temperature data TD4.

While the first heating circuit 53_1, the second heating circuit 53_2, the third heating circuit 53_3, and the fourth heating circuit 53_4 are not all turned on, the temperatures of the first memory region 55_1 and the third memory region 55_3 may generally be higher than the temperatures of the second memory region 55_2 and the fourth memory region 55_4 due to heat generated by an operation of the host device 10. Accordingly, temperature control with respect to the core die CD may be performed so that the temperatures of the second memory region 55_2 and the fourth memory region 55_4 are maintained the same as the temperatures of the first memory region 55_1 and the third memory region 55_3.

Specifically, the logic die (e.g., the logic die LD shown in FIGS. 3 and 4) may receive the first temperature data TD1 with respect to the first memory region 55_1 from the first temperature sensor 52_1, receive the second temperature data TD2 with respect to the second memory region 55_2 from the second temperature sensor 52_2, receive the third temperature data TD3 with respect to the third memory region 55_3 from the third temperature sensor 52_3, and receive the fourth temperature data TD4 with respect to the fourth memory region 55_4 from the fourth temperature sensor 52_4.

Because the temperatures of the first memory region 55_1 and the third memory region 55_3 are higher than the temperatures of the second memory region 55_2 and the fourth memory region 55_4, values of the first temperature data TD1 and the third temperature data TD3 may be greater than values of the second temperature data TD2 and the fourth temperature data TD4. The logic die LD may determine that the temperatures of the second memory region 55_2 and the fourth memory region 55_4 are lower than the temperatures of the first memory region 55_1 and the third memory region 55_3 based on the value of the first temperature data TD1, the value of the second temperature data TD2, the value of the third temperature data TD3, and the value of the fourth temperature data TD4.

The logic die LD may provide the control signal CONT to turn off the first heating circuit 53_1 and the third heating circuit 53_3 to the first heating circuit 53_1 and the third heating circuit 53_3 so that the temperatures of the first memory region 55_1, the second memory region 55_2, the third memory region 55_3, and the fourth memory region 55_4 are maintained the same, and may provide the control signal CONT to turn on the second heating circuit 53_2 and the fourth heating circuit 53_4 to the second heating circuit 53_2 and the fourth heating circuit 53_4.

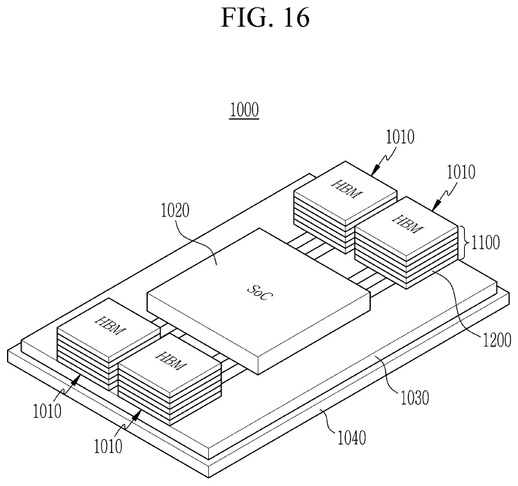

FIG. 16 is a perspective view illustrating an example of a semiconductor device.

Referring to FIG. 16, a semiconductor device 1000, as a semiconductor package, may be a memory module including at least one memory device 1010 and a system-on-chip (SoC) 1020 which are mounted on a package substrate 1040 such as a printed circuit board. In some implementations, a memory device described with reference to FIGS. 1 to 15 may be applied to the memory device 1010.

An interposer 1030 may be further selectively provided on the package substrate 1040. The memory device 1010 may be formed as a chip-on-chip (CoC). The memory device 1010 may include a memory die 1100 including at least one core die stacked on a logic die 1200. The memory die 1100 and the logic die 1200 may be connected to each other by a through silicon via.

In some implementations, the memory device 1010 may be a high-bandwidth memory of 500 GB/sec to 1 TB/sec, or more.

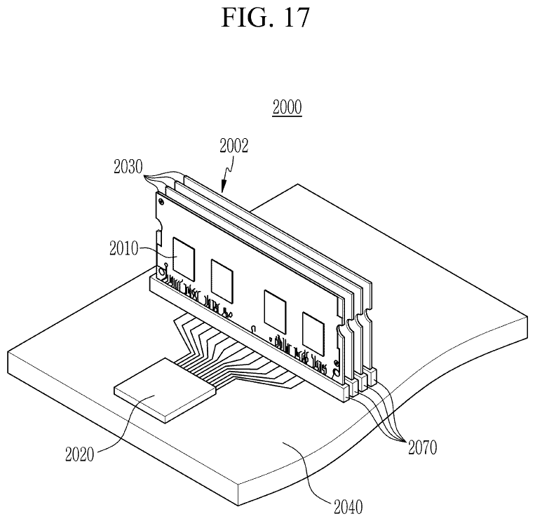

FIG. 17 is a perspective view illustrating an example of a semiconductor device.

Referring to FIG. 17, a semiconductor device 2000 is a dual in-line memory module (DIMM) system in which semiconductor chips are mounted on both sides of a printed circuit board, and may include a memory module 2002 including at least one PCB 2030 and a memory controller 2020. The memory controller 2020 may be mounted on a main board 2040, and the PCB 2030 may be electrically connected to the main board 2040 through a plurality of connection sockets.

A memory device 2010 may be formed as a CoC and may be mounted on both sides of the PCB 2030. The memory controller 2020 and the memory device 2010 may be electrically connected to the PCB 2030 through a bus in the main board 2040. In some implementations, the memory device 2010 may include a stack structure of a memory die and a logic die. In some implementations, the memory device described with reference to FIGS. 1 to 15 may be applied to the memory device 2010.

In some implementations, the memory device 2010 may be a high-bandwidth memory of 500 GB/sec to 1 TB/sec, or more.

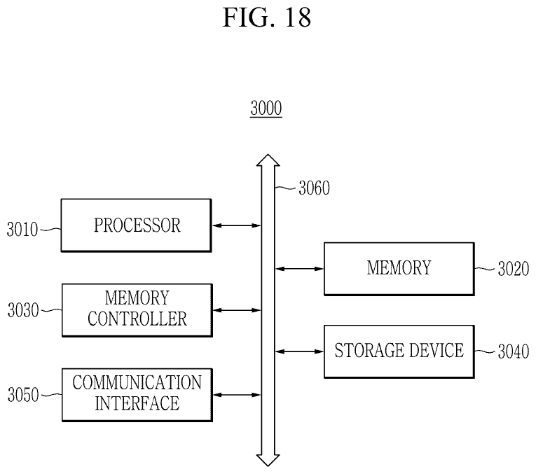

FIG. 18 is a schematic block diagram of an example of a computing device.

Referring to FIG. 18, a computing device 3000 includes a processor 3010, a memory 3020, a memory controller 3030, a storage device 3040, a communication interface 3050, and a bus 3060. The computing device 3000 may further include other general components.

The processor 3010 controls the overall operation of each component of the computing device 3000. The processor 3010 may be implemented as at least one of various processing units such as a CPU, an AP, and a GPU.

The memory 3020 stores various types of data and commands. The memory 3020 may be implemented as the memory device described with reference to FIGS. 1 to 15. The memory controller 3030 controls transmission of the data or the commands to and from the memory 3020. In some implementations, the memory controller 3030 may be provided as a separate chip from the processor 3010. In some implementations, the memory controller 3030 may be provided as an internal configuration of the processor 3010.

The storage device 3040 non-temporarily stores programs and data. In some implementations, the storage device 3040 may be implemented as a non-volatile memory. The communication interface 3050 supports wired/wireless Internet communication of the computing device 3000. In addition, the communication interface 3050 may support various communication methods other than Internet communication. The bus 3060 provides a communication function between components of the computing device 3000. The bus 3060 may include at least one type of bus according to a communication protocol between components.

In some implementations, each component or combination of two or more components described with reference to FIGS. 1 to 15 may be implemented as a digital circuit, a programmable or non-programmable logic device or array, an application specific integrated circuit (ASIC), etc.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the disclosure have been described in detail above, the scope of the disclosure is not limited thereto, and various modifications and improvements made by those of ordinary skill in the field also belong to the scope of the disclosure.

What is claimed is:

1. A memory device comprising:
a logic die configured to output a control signal based on temperature data; and
a first core die comprising
a first plurality of memory cells configured to store data,
a first temperature sensor configured to measure a temperature of the first plurality of memory cells and to output first temperature data based on the temperature of the first plurality of memory cells, and
a first heating circuit configured to generate heat based on the control signal and the first temperature data.

2. The memory device of claim 1, wherein the first heating circuit includes
a resistor connected between a first node and a second node, the first node and the second node being configured to receive the first temperature data,
a transistor connected between the first node and the resistor, the transistor including a gate configured to receive the control signal, and
a voltage amplifier connected between the resistor and the second node.

3. The memory device of claim 2, wherein:
the logic die is configured to output the control signal to cause the transistor to turn on based on the first temperature data being equal to or less than a specific value.

4. The memory device of claim 2, wherein:
the logic die is configured to output the control signal having a bias voltage to cause the transistor to break down based on the first temperature data being equal to or greater than a specific value.

5. The memory device of claim 2, comprising:
a second core die including
a second plurality of memory cells configured to store data,
a second temperature sensor configured to measure a temperature of the second plurality of memory cells and to output second temperature data based on the temperature of the second plurality of memory cells, and
a second heating circuit configured to generate heat based on the control signal and the second temperature data,
wherein the first core die includes a multiplexer configured to output at least one of the first temperature data or the second temperature data to an input terminal of the transistor.

6. The memory device of claim 5, wherein:
the first core die and the second core die are stacked in a first direction.

7. The memory device of claim 5, wherein:
the logic die is configured to output, to the multiplexer, a selection signal configured to cause the multiplexer to output the second temperature data based on a value of the first temperature data being less than a value of the second temperature data.

8. The memory device of claim 6, wherein:
the first core die is configured to receive the second temperature data through a first through silicon via, the first through silicon via extending through the first core die and the second core die in the first direction.

9. The memory device of claim 8, wherein:
the logic die and the first core die are stacked in the first direction,
the logic die is configured to provide the control signal to the first core die through a second through silicon via different from the first through silicon via, and
the second through silicon via extends through the first core die and the second core die in the first direction.

10. The memory device of claim 1, wherein:
the first heating circuit is configured to surround the first plurality of memory cells.

11. The memory device of claim 1, wherein:
the first plurality of memory cells include a first memory cell and a second memory cell, and
the first heating circuit includes a second heating circuit surrounding the first memory cell and a third heating circuit surrounding the second memory cell.

12. The memory device of claim 1, wherein:
the first heating circuit comprises at least one of poly gate, tungsten, aluminum, or copper.

13. A memory device comprising:
a plurality of core dies stacked in a first direction and configured to provide temperature data, the plurality of core dies including a first core die, a second core die, and a third core die; and
a logic die configured to output a control signal based on the temperature data,
wherein the plurality of core dies are configured to provide the temperature data through a first through silicon via, the first through silicon via extending through the plurality of core dies in the first direction, and
wherein the second core die includes a heating circuit configured to heat the second core die based on first temperature data of the first core die, second temperature data of the second core die,, third temperature data of the third core die, and the control signal.

14. The memory device of claim 13, wherein the heating circuit includes
a resistor connected between a first node and a second node that are configured to receive at least part of the temperature data,
a transistor connected between the first node and the resistor, the transistor including a gate that is configured to receive the control signal, and
a voltage amplifier connected between the resistor and the second node.

15. The memory device of claim 14, wherein:
the logic die is configured to output the control signal to cause the transistor to break down based on a value of the temperature data of the second core die being less than a value of the temperature data of the first core die and a value of the temperature data of the third core die.

16. The memory device of claim 14, wherein:
the logic die is configured to output the control signal having a bias voltage to cause the transistor to turn off based on the temperature data of the second core die being equal to or greater than a specific value.

17. The memory device of claim 13, wherein the logic die is configured to
output the control signal to cause a heating circuit of the first core die to turn on based on the temperature data of the first core die being less than or equal to a first value,
output the control signal to cause the heating circuit of the second core die to turn on based on the temperature data of the second core die being less than or equal to a second value different from the first value, and
output the control signal to cause a heating circuit of the third core die to turn on based on the temperature data of the third core die being less than or equal to a third value different from the first value and the second value.

18. The memory device of claim 17, wherein:
the second value is less than the first value and greater than the third value.

19. The memory device of claim 18, wherein:
the logic die, the first core die, the second core die, and the third core die are stacked in the first direction, and
the logic die is configured to provide the control signal to the first core die, the second core die, and the third core die through a second through silicon via different from the first through silicon via, the second through silicon via extending through the first core die, the second core die, and the third core die in the first direction.

20. A semiconductor device comprising:
a host device; and
a memory device comprising
a logic die configured to output a control signal based on first temperature data and second temperature data, and
a core die stacked on the logic die in a first direction,
wherein the core die comprises
a first memory region comprising
a plurality of first memory cells,
a first temperature sensor configured to measure temperature of the plurality of first memory cells and to output the first temperature data based on the temperature of the plurality of first memory cells, and
a first heating circuit configured to heat the plurality of first memory cells based on the control signal and the first temperature data, the first heating circuit being disposed adjacent to the host device,
a second memory region comprising
a plurality of second memory cells,
a second temperature sensor configured to measure temperature of the plurality of second memory cells and to output the second temperature data based on the temperature of the plurality of second memory cells, and
a second heating circuit configured to heat the plurality of second memory cells based on the control signal and the second temperature data, the second heating circuit being disposed opposite to the host device with respect to the first memory region, and
wherein the control signal is configured to cause the first heating circuit to turn off and to cause the second heating circuit to turn on.
